(19) United States
(12) Patent Application Publication
(10) Pub. No.: US 2007/0250745 A1
(43) Pub. Date: Oct. 25, 2007

(54) METHOD AND SYSTEM FOR TESTING A MEMORY DEVICE

(75) Inventors: Ralf Schneider, Muenchen (DE); Martin Versen, Feldkirchen-Westerham (DE); Juergen Zielbauer, Tocufkirchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/735,176

(22) Filed: Apr. 13, 2007

(30) Foreign Application Priority Data
Apr. 13, 2003 (DE) 10 2006 017 546.8

(51) Int. Cl. G11C 29/00

(52) U.S. Cl. 714/718

(57) ABSTRACT

A system and method for testing a memory device is disclosed. One embodiment includes a plurality of memory cells. Each of the memory cells can be controlled by an address. A test memory for storing test results is provided. An address comparing unit is configured to determine whether the address of a memory cell lies in a predetermined address space. A controllable unit for storing test results is connected with the test memory and the address comparing unit. The controllable unit is controlled by the address comparing unit such that error information of the tested memory cell is only stored in the test memory if the address of the tested memory cell lies in the selected address space.

### Cross-Reference to Related Applications

This Utility Patent Application claims priority to German Patent Application No. DE 10 2006 017 546.8 filed on Apr. 13, 2006, which is incorporated herein by reference.

### Background

The present invention relates to a method and to a system for testing a memory device.

During the testing of memory devices, the information whether a memory cell can be written and read without error is usually stored for every single memory cell. This information is collected separately for every memory cell since the errors otherwise cannot be allocated to the individual memory cells. The information is in particular necessary for an evaluation of test results.

Systems for testing memory devices require a test memory to be able to store the test results. The test systems therefore include a large number of quick and thus expensive memory devices. For reasons of costs, the test memory available in the test system should be chosen smaller than the size of the tested memory. This has, however, as a consequence that the test results of all memory cells of the tested memory device cannot be stored in the test memory. Thus, there either accrue high acquisition costs, or the analysis capability of the test system is strongly restricted. The information stored in the test memory can be evaluated after the test procedure only. Due to the data amount to be processed, the processing effort is great and the latency for evaluating the test results is very long.

Conventionally, different methods have been used to find a good compromise between the analysis capability of the test results and the costs for the test memory. The memory for storing the test results implemented in conventional test systems is smaller than the one that would have to be used for storing all measuring results. Instead of storing all test results, only a limited number of test results is stored. Conventionally, the test memory is only filled with information of measuring results which indicate a malfunction of memory cells. Thus, all test results that merely confirm the functionability of the memory are omitted. This means that the evaluation of the test results is performed at least partially while the test is running. Such an evaluation is, as a rule, only restricted to the finding of whether or not an error existed at all.

If the test memory is not large enough to accept all the information of faulty memory cells, only those test results are stored that occur first in the chronological order of the test. This is due to the fact that the error information is stored as soon as it occurs. If the test memory is completely filled, all the errors that are collected later can no longer be written in the test memory. The chronology of the test determines which error information is stored and which error information is not stored.

A disadvantage of this method is in particular that the user has no possibility of evaluating errors that occur later. Therefore, test systems have been developed in which the user can define the time windows for the acceptance of test result. But here, too, further errors occurring after the filling of the test memory within the time window have to be ignored.

The afore-described test systems are, however, little practical. This is because, for the evaluation and assessment of memory errors, it is first of all irrelevant in which chronological order they occur due to the selected test method. In this respect, the restriction to time windows indeed allows the user to collect errors which he could not at all collect otherwise. For the specific search for errors and their reasons, however, this method is very pedestrian and time-consuming. Furthermore, in the case of block-like failures of memory cells it is no longer possible to analyze or even to collect further failures since the block-like failures have already filled the limited test memory. Such a block-like failure occurs, for instance, if a large number of memory cells does not operate correctly due to the failure of a central control element.

For these and other reasons, there is a need for the present invention.

### Brief Description of the Drawings

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates an address space of a memory device to be tested.

FIG. 2 illustrates a first time diagram for a read access to the memory device to be tested in accordance with a first embodiment.

FIG. 3 illustrates a second time diagram for a read access to the memory device to be tested in accordance with the first embodiment.

FIG. 4 illustrates a time diagram for a read access to the memory device to be tested in accordance with a second embodiment.

FIG. 5a illustrates a schematic structure of a system for testing a memory device in accordance with the first embodiment.

FIG. 5b illustrates a schematic structure of a system for testing a memory device in accordance with the second embodiment.

FIG. 6 illustrates a schematic structure of a system for testing a memory device in accordance with a third embodiment.

### Detailed Description

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide a method and a system for testing memory devices which enable a practical and cost-efficient test of the memory device despite a limited test memory.

One embodiment provides a system for testing a memory device that includes a plurality of memory cells. Each of the memory cells can be controlled by using an address. A test memory for storing test results is provided. An address comparing unit is designed to determine whether the address of a memory cell lies within a predetermined address space. A controllable unit for storing test results is connected with the test memory and the address comparing unit. The controllable unit is controlled by the address comparing unit such that error information of the tested memory cell is only stored in the test memory if the address of the tested memory cell lies within the selected address space.

The system thus provides that the decision of whether a faulty measuring result is stored in the test memory is made dependent on the address of the pertinent memory cell. This selection is based on the finding that, when analyzing errors in a memory device, usually only a particular address space around the error to be analyzed is of interest. By being able to select the memory area to be tested due to the selected address space, it is possible to more exactly analyze the address space of a memory which is affected by an error in a simple and practical manner. Without increasing the costs for the test system by using increased test memory it is possible to obtain precious test results in a simpler and more practical manner.

In one embodiment, the system for testing a memory device includes a central control unit that is provided to calculate address and control signals for the memory cells in real time during the testing of the memory device. A real-time system is spoken of if a system calculates a result within a previously specifically defined period with guarantee, i.e. before a particular time limit has been reached. A real-time system thus has to supply a calculation result not just with the correct value, but also in time.

In accordance with one embodiment, it is decided in real time whether the error information of the tested memory cell is stored in the test memory. The decision takes place at the time at which the error information is collected. The decision about whether the error information is stored is made in time, i.e. a decision is made so quickly that the testing of the memory cells is not or unnoticeably delayed thereby.

The address comparing unit may, for instance, be connected to the central control unit. The control unit transmits the address of the tested memory cell to the comparing unit. This is possible since the central control unit has the information of the tested memory cell during the test procedure. This information is in particular available if the central control unit is destined to calculate address and control signals for the memory cells in real time during the test of the memory device.

The central control unit may, however, also be destined to calculate address and control signals for the memory cells prior to the test of the memory device. In this case, the address data of the currently tested memory cell are not always available, so that the address comparing unit cannot obtain this information off-hand from the control unit. In the case of such an implementation of the present invention, local memories are set up for the address and control signals calculated by the central control unit for the memory cells to be tested.

The central control unit, for instance, is not involved in the test event during the test. The advantage thereof is that the test itself is not delayed by the calculations of the central control unit. The central control unit may be used otherwise during the test. The resources of the test system may thus be utilized more efficiently.

However, in a test system in which the address and control signals are calculated prior to the actual test procedure, suitable measures are required to be able to allocate the test results to the tested memory cells and especially to their addresses. For this reason, the central control unit determines a chronology of the test of the memory cells prior to the test of the memory device. Thus, the point in time for the occurrence of an error is correlated with the memory cell tested at this point in time. By using the point in time of the occurrence of test results, the corresponding address of the tested memory cell can be determined. To this end, a cycle counter is provided which is configured to calculate the point in time in real time within the chronology of the test. The address comparing unit is connected with the cycle counter and configured to determine the address of the currently tested memory cell by using the point in time received from the cycle counter. If an error is detected at this point in time, the error can be correlated with the address of the tested memory cell.

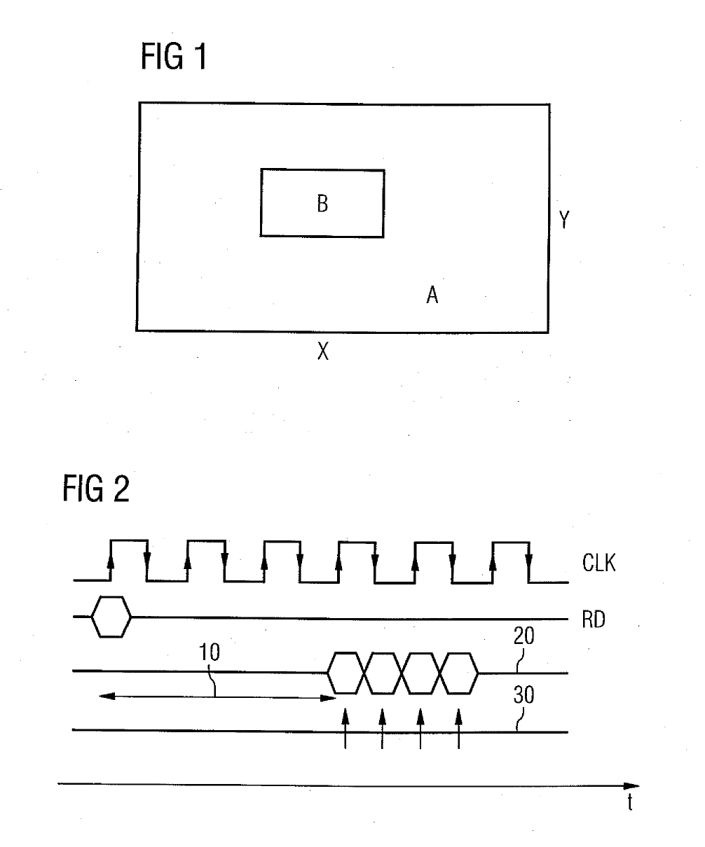

The address space of the memory illustrated in FIG. 1 includes two different areas A and B. The address space A includes the addresses of all memory cells of the memory device to be tested. The address space is embedded in a coordinate system consisting of X and Y axes. Each address corresponds to exactly one point in the coordinate system. The entire address space A corresponds to a rectangle.

Furthermore, a second address space B is illustrated in FIG. 1. This address space B forms a subset of the entire addressable address space. The address space B determines the space of those faulty measuring results that are stored in an inventive test memory. Only those memory cells whose address lies within the address space B are—if they are faulty—stored in the test memory for storing the faulty measuring results.

The address space B that is plotted as a rectangle in FIG. 1 is not necessarily a rectangle. Without limitation of the scope of protection, the embodiments include any address space selection possibilities. This means that any partial address space within the entire address space A may be determined as particular address space B whose faulty memory cells are destined to be stored in the test memory. All address spaces that can be defined by the states of all address bits and logic operations (smaller, greater, equal, and, or, exclusive-or, not) can serve as predetermined address space B.

FIG. 2 illustrates a first time diagram for a read access to the memory device to be tested in accordance with a first embodiment. The time diagram includes a time axis t indicating the chronology. A plurality of signals are illustrated above the time axis t. The reference number CLK represents a clock signal. The clock signal is rectangular. The rising edges of the clock signals are adapted to trigger further signals.

A read command signal RD is illustrated below the clock signal CLK. This signal is used to read data from a predetermined memory cell. Such a read process is in particular performed for testing the memory cells. If the read-out signal corresponds to the previously input memory value, the memory cell is functionable. Otherwise, an error of the memory cell was collected.

If the address of the tested and faulty memory cell lies within the predetermined address space B, the address of the memory cell is stored in the test memory. As the case may be, further information about the faulty memory cell may also be stored in the test memory. In particular information about the kind of the collected error might be recorded in the test memory in the case of more complex tests.

A certain latency 10 elapses between the reading out of the memory cell due to the read command RD and the receipt of the corresponding data 20. This latency 10 is determined by the memory hardware used. The read-out data 20 are in turn synchronized with the clock signal CLK. A strobe signal 30 is plotted below the data signal 20. For the address space B plotted in FIG. 1, the data assessment (strobe) is enabled, so that these data can be stored in the test memory for the case of a faulty memory cell. The strobe arrows in FIG. 2 reveal that the addresses of all read-out memory cells lie within the predetermined address space B.

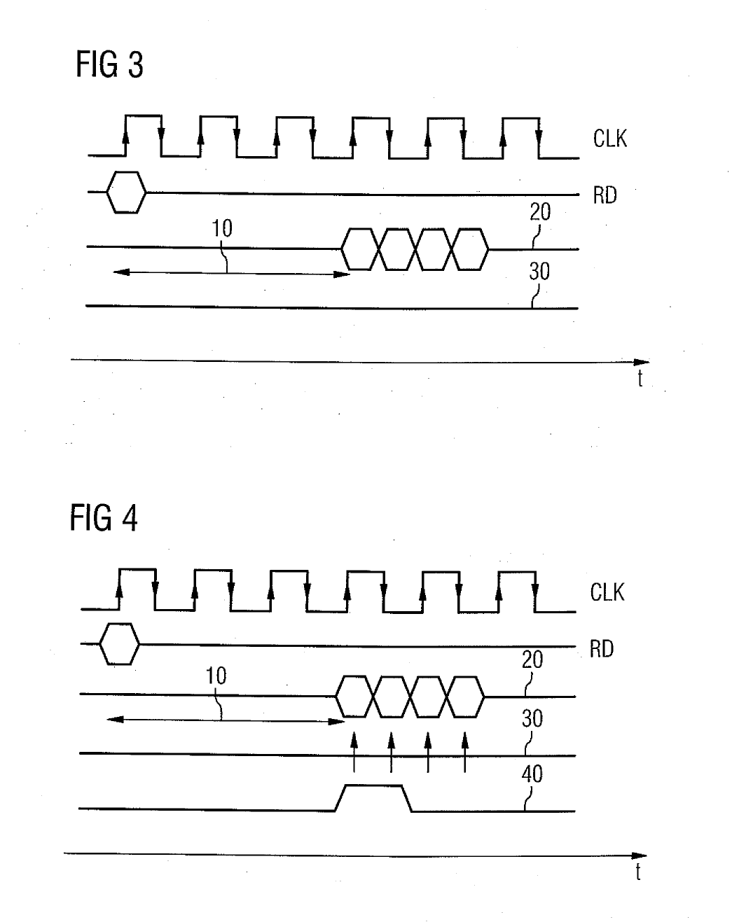

In case the read-out memory cells do not lie within the address space B, the tester does not assess the memory data due to the missing strobe signal. Due to the missing assessment, errors which would otherwise have to be stored in the test memory are not collected. Irrespective of whether the memory cell is faulty or not, the result of the error analysis is discarded if the address space does not lie within the memory space B. This case is illustrated in FIG. 3. FIG. 3 again illustrates the clock signal CLK, the data read signal RD, the read-out data 20, and the strobe signal 30. Since, however, no strobe arrows are plotted below the corresponding data in FIG. 3, no information whatsoever is stored in the test memory about the read-out data and their memory cells.

FIG. 4 illustrates a time diagram for a read access to the memory device to be tested in accordance with a second embodiment. In FIG. 4, a time axis is also provided. The reference numbers used for FIGS. 2 and 3 designate the same subject matters in FIG. 4. In addition to the strobe signal 30, a strobe activation signal 40 is provided in FIG. 4.

FIG. 4 illustrates a mixed read access to memory cells from the address spaces A and B. The data from the different address spaces A and B follow each other directly in FIG. 4. In this case, the allocation of the data 20 to the different address spaces in real time by using the strobe signal is a problem. The problem of the allocation of the read-out data to the different address spaces is solved in this embodiment by using a strobe activation signal 40. This signal is generated in real time by a central control unit so as to allocate the read-out data to the different address spaces.

The differentiation between data from the address spaces A and B is performed by the strobe activation signal 40. As soon as the strobe activation signal 40 is active or has assumed a high level, respectively, all the data packets 20 thereabove are assessed as originating from the address space B. Vice versa, in the case of a low level of the strobe activation signal 40, the data packets are not from the memory space B. Consequently, the first two data packets in FIG. 4 are active since they lie in the address space B. The last two data packets of the data signal 20 in FIG. 4 do not lie in the address space B. The results of the error assessment with respect to the last data packets are not stored in the test memory.

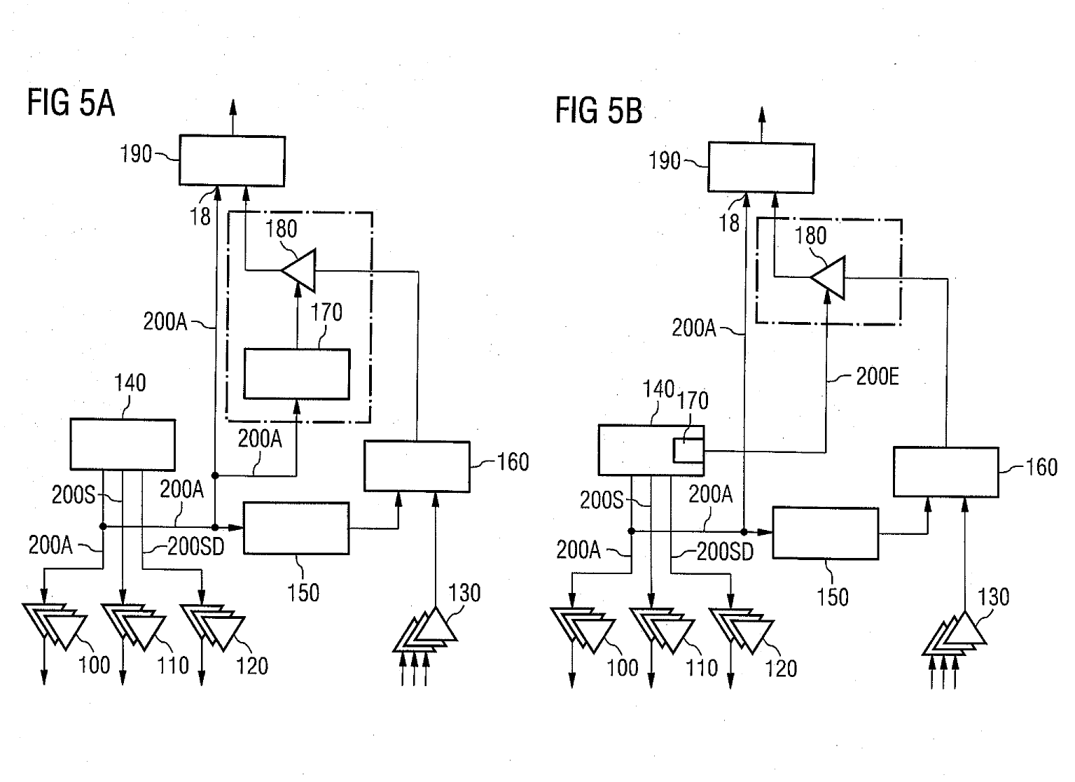

FIG. 5a illustrates a schematic structure of a system for testing a memory device in accordance with the first embodiment. This is an embodiment in which the control signals are calculated in real time during the test of the memory. After each test of a particular memory cell, the control signals for controlling and testing the next memory cell are calculated in real time. To this end, the system includes a central control unit 140 that is connected with a signal driver 100 for the addresses of the memory cells, a signal driver 110 for the control signals, and a signal driver 120 for the write data. The central control unit 140 has always knowledge of the address of the currently tested memory cell.

The central control unit 140 calculates all the necessary address data, write data, and read data at the point in time of the test of a memory cell. For testing the memory cell, it is first of all written with predetermined write data. Subsequently, the data are again read out from the memory. The required control commands are calculated by the central control unit. A signal receiver 130 subsequently collects the read data 20 from the memory cell.

The read-out data characterize the actual state of the memory cell. The target state of the tested memory cell is characterized by the previously written data. A data comparing unit 160 is destined to compare the target state with the actual state. To this end, the comparing unit 160 receives the read-out data from the signal receiver 130 and the expected read data (target state) from a calculating unit 150 for the expected read data. The calculating unit in turn receives the address of the tested memory cell from the central control unit 140. By using the address, the calculating unit 150 determines which data were written in the corresponding memory cell before. These data (target state) are transmitted to the data comparing unit 160. If a discrepancy between the target state and the actual state is determined by the data comparing unit 160, it outputs an error signal.

The error signal of the data comparing unit 160 is, however, not transmitted off-hand to a test memory 190. Only such error data are stored that were determined for memory cells within the predetermined address space B. To this end, an address comparing unit 170 is provided in FIG. 5a. While the data comparing unit determines whether an error exists, the address comparing unit 170 determines whether the error relates to a memory cell within the predetermined address space B. If the tested memory cell should lie within the address space B, the error signal is transmitted to the test memory 190. To this end, a controllable unit 180 for transmitting the error signal from the data comparing unit 160 to the test memory 190 is provided. The controllable unit 180 is connected with the address comparing unit 170 which determines whether the error signal is transmitted from the data comparing unit 160 to the test memory 190. As controllable unit 180, in particular a transistor may be provided, the gate or base of which is controlled by the address comparing unit. Source and drain or collector and emitter, respectively, of the transistor are each connected with the data comparing unit 160 and the test memory 190.

In the case of a faulty memory cell within the predetermined memory space B, the test memory 190 receives the error signal from the controllable unit 180. At the same time, the test memory 190 receives, via an input 18, the address of the tested faulty memory cell from the central control unit. Thus, the address of the faulty memory cell can be stored in the test memory 190. A user can read out the addresses and further information from the test memory to assess the state of the tested memory device.

FIG. 5b illustrates a schematic structure of the inventive system for testing a memory device in accordance with the second embodiment of the present invention. Identical reference numbers in FIGS. 5a and 5b designate the same subject matters. The test system illustrated in FIG. 5b largely resembles the system for testing memory devices illustrated in FIG. 5a. The address comparing unit 170 is, however, designed differently to that of FIG. 5a. While the address comparing unit 170 of the first embodiment in accordance with FIG. 5a is realized by an own component, in FIG. 5b the central control unit 140 performs the address comparison. The controllable unit 180 in FIG. 5b is, via the line 200E for the strobe activation signal 40, connected with the control unit 140. The central control unit performs the address comparison in real time. The strobe activation signal 40 transmitted via the line 200E permits a data storage only if the data comparison relates to a date from the selected address space. Otherwise, the unit 180 controlled via the line 200E prevents the result of the data comparison from being stored in the test memory.

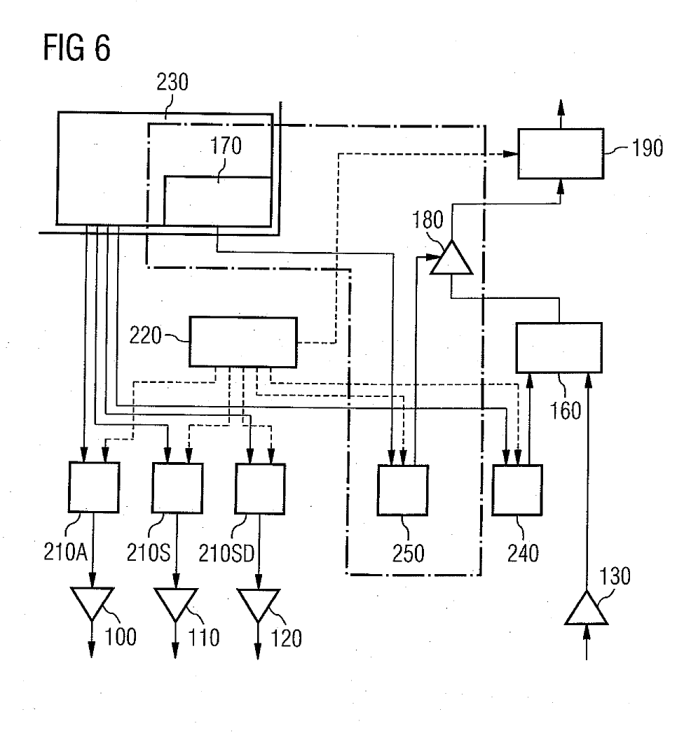

FIG. 6 illustrates a schematic structure of a system for testing a memory device in accordance with a third embodiment of the present invention. Similar components in FIG. 6 have the same reference numbers as in FIG. 5a.

In contrast to FIG. 5a, the test system according to FIG. 6 has no central control unit that calculates the control and address signals in real time. The calculating unit 230 provided in FIG. 6 is provided to calculate the necessary control signals for the respective signal drivers 100, 110, and 120 before the test is performed. The corresponding address, control, and write data are stored in local memories before the test is performed. The signal driver 100 for addresses is connected to the local memory 210A for addresses. Correspondingly, the local memory for control signals and write data 210S and 210D is connected to the respective signal drivers for control signals and write data 110 and 120.

As soon as the test has been initiated, the calculating unit does not monitor the respective address and control data. This information is, during the test procedure and controlled by a cycle counter, in parallel transmitted to the pertinent signal drivers 100, 110, and 120 and relayed to the data comparing block 160. During the test, the addresses for the memory cells to be assessed are unknown. However, the order in which the test is performed is predetermined. To this extent, by using the point in time of the collection of an error information, it can be gathered which memory cell with which address is concerned by the error information. Furthermore, it is possible to determine, by using the point in time of the collection of read data which target data are to be read out.

The data comparing unit 160 in FIG. 6 is connected both to the signal receiver 130 and to a local memory 240 for the expected read data. The local memory 240 receives the point in time of the test procedure at any time from the cycle counter 220. Based thereon, the local memory 240 determines which read data the signal receiver 130 has to receive. The data comparing unit 160 determines whether the read data from the local memory 240 (target data) correspond with the actual data from the signal receiver 130. In the case of a deviation of both input signals of the data comparing unit 160, it outputs an error signal.

The address comparing unit 170 in FIG. 6 does not control the controllable unit 180 directly as in the first embodiment. Instead, an additional local memory 250 is provided for address comparison. The local memory determines by using the cycle counter which address the memory cells corresponding to the read data of the signal receiver have. The address comparing unit 170 determines whether the determined address falls in the predetermined address space B. The address comparing unit 170 checks, before the test is performed, each address that is to be read later as to whether it lies within the space B that is relevant for the evaluation, or not. If the address lies in the space B, the error signal is, during the later test performance, transmitted to the test memory for storing the error address. Otherwise, the error signal is suppressed, so that no error can be stored, and thus no entry in the test memory is consumed, either.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for testing a memory device, comprising:
providing a memory device having a test memory;
selecting an address space consisting of a subset of a set of all addresses of tested memory cells;
checking whether an address of a memory cell to be tested lies within the selected address space;
assessing whether the memory cell is faulty; and
storing error information of the tested memory cell in the test memory only if the memory cell is faulty and lies in the selected address space.

2. The method of claim 1, comprising determining in real time whether the error information of the tested memory cell is stored in the test memory using a central control unit.

3. The method of claims 1, comprising writing the memory cell to be tested with read data, the memory cell is read out, and the read-out read data is compared with the read-in read data so as to determine whether the memory cell is faulty.

4. The method of claim 1, comprising performing the process of checking whether the memory cell lies in a predetermined address space before testing the memory cell.

5. A method for testing a memory device, comprising:
providing a memory device having memory cells controllable by using an address, and a test memory for storing test results, wherein the test memory is not large enough to accept the test results for all memory cells;
selecting an address space consisting of a subset of a set of all addresses of the memory cells;
testing a plurality of the memory cells;
checking whether an address of a memory cell to be tested lies within the selected address space;
assessing whether the memory cell is faulty; and
storing error information of the tested memory cell in the test memory only if the memory cell is faulty and lies in the selected address space.

6. The method of claim 5, comprising monitoring testing of the memory cell via a central control unit; and determining in real time whether the error information of the tested memory cell is stored in the test memory using the central control unit.

7. The method of claims 5, comprising writing the memory cell to be tested with read data, the memory cell is read out, and the read-out read data are compared with the read-in read data so as to determine whether the memory cell is faulty.

8. The method of claim 5, comprising performing the process of checking whether the memory cell lies in a predetermined address space before testing the memory cell.

9. The method of claim 8, comprising testing only those memory cells whose address lies in the selected address space.

10. The method of claim 5, comprising performing the process of checking whether the memory cell lies in the selected address space is performed after testing the memory cell.

11. A system for testing a memory device, wherein the memory device having a plurality of memory cells that can each be controlled by using an address, comprising:
a test memory for storing test results;
an address comparing unit configured to determine whether an address of a memory cell lies in a predetermined address space;
a controllable unit for storing test results, wherein the controllable unit communicates with the test memory and the address comparing unit such that error information of the tested memory cell is only stored in the test memory if the address of the tested memory cell lies in the selected address space.

12. The system of claim 11, comprising a central control unit configured to calculate address and control signals for the memory cell in real time during testing of the memory device.

13. The system of claim 12, comprising wherein the address comparing unit is configured to receive the address of the tested memory cell from the control unit.

14. The system of claim 11, comprising a central control unit configured to calculate address and control signals for the memory cells before the test of the memory device.

15. The system of claim 14, comprising local memories for the address and control signals calculated by the central control unit for the memory cells to be tested.

16. The system of claims 14, wherein the central control unit is configured to determine a chronology of the test of the memory cells before the test of the memory device.

17. The system of claim 16, comprising a cycle counter that is configured to calculate the point in time within the chronology of the test in real time.

18. The system of claim 17, comprising wherein the address comparing unit is connected with the cycle counter and is configured to determine the address of the currently tested memory cell by the point in time received from the cycle counter.

19. The system of claim 11, comprising wherein the central control unit acts as the address comparing unit.

20. A system for testing a memory device, wherein the memory device having a plurality of memory cells that can each be controlled by using an address, comprising:
a test memory for storing test results;
address means for comparing configured to determine whether an address of a memory cell lies in a predetermined address space;
control means for storing test results, wherein the control means communicates with the test memory and the address comparing means such that error information of the tested memory cell is only stored in the test memory if the address of the tested memory cell lies in the selected address space.

21. The system of claim 20, comprising a central control unit configured to calculate address and control signals for the memory cell in real time during testing of the memory device.

22. The system of claim 21, comprising wherein the address comparing unit is configured to receive the address of the tested memory cell from the central control unit.

23. The system of claim 20, comprising a central control unit configured to calculate address and control signals for the memory cells before the test of the memory device.
